(19) United States
(12) Patent Application Publication
(10) Pub. No.: US 2019/0013317 A1
(43) Pub. Date: Jan. 10, 2019

(54) High-Density Volatile Random Access Memory Cell Array and Methods of Fabrication

(71) Applicant: TC Lab, Inc., Gilroy, CA (US)

(72) Inventors: Harry Luan, Saratoga, CA (US); Bruce L. Bateman, Fremont, CA (US); Valery Axelrad, Woodside, CA (US); Charlie Cheng, Los Altos, CA (US)

(21) Appl. No.: 16/032,056

(22) Filed: Jul. 10, 2018

Related U.S. Application Data
(60) Provisional application No. 62/530,785, filed on Jul. 10, 2017.

(51) Int. Cl. H01L 27/102; H01L 21/8229; H01L 21/8249

(52) U.S. Cl. CPC H01L 27/1027; H01L 29/1012; H01L 21/8249; H01L 21/8229

(57) ABSTRACT

Thyristor memory cell arrays and their fabrication have improved features. Assist-gates between thyristor memory cells in an array operate on both sides of an assist-gate. The assist-gates can be arranged in various ways for optimized performance and the materials of the assist-gate are selected to control the bias voltage of the assist-gate in operation. The PNPN (or NPNP) thyristor layers of the memory cell can be fabricated in different process flows according to manufacturing concerns and the dopant concentrations of the layers are selected to reduce temperature sensitivity of the memory cell.

### CROSS-REFERENCE TO RELATED APPLICATIONS

This patent application claims priority to U.S. Provisional Patent Application No. 62/530,785, entitled “Vertical Thyristor Dynamic Random Access Memory and Methods of Fabrication,” filed Jul. 10, 2017, which is incorporated by reference herein.

### BACKGROUND OF THE INVENTION

This invention relates to semiconductor devices for information storage. In particular, the invention relates to vertical thyristors in dynamic random access memories (DRAM) and methods for fabrication of such memories.

Various DRAM semiconductor cell structures have been proposed using thyristors. The assignee herein has various co-pending patent applications which describe several thyristor semiconductor structures for DRAMs, and the processes for manufacturing them. See, e.g., U.S. patent application Ser. No. 15/197,640, filed Jun. 29, 2016, and entitled “Thyristor Memory Cell with Gate in Trench Adjacent the Thyristor,” and U.S. Patent Application 62/345,203, filed Jun. 29, 2015, from which the above application claims priority, each of which is incorporated by reference herein.

This application describes improvements over the technology described in those applications.

### BRIEF SUMMARY OF THE INVENTION

The present invention provides for an integrated circuit array of thyristor memory cells comprising: a set of cathode lines; a set of anode lines; a plurality of thyristor memory cells arranged in an array, each thyristor memory cell having a cathode region connected to a cathode line and an anode region connected to an anode line and at least one base region between the cathode region and anode region; and a set of assist-gate electrodes, each assist-gate electrode located between pairs of thyristor memory cells, a portion of the assist-gate electrode adjacent to, but displaced from, the at least one base region of each of the thyristor memory cell pair to form an electrical coupling with the each of the thyristor memory cell pair.

The present invention provides for the integrated circuit array wherein the set of assist-gate electrodes comprises a conductive material selected to control a bias voltage for a thyristor memory cell, the bias voltage applied to the assist-gate electrode for switching the state of the thyristor memory cell.

The present invention further provides for a method of fabricating an integrated circuit array of thyristor memory cells. The method has the steps of: forming a first set of parallel trenches in a semiconductor substrate; forming a second set of parallel trenches in the semiconductor substrate, the second set of parallel trenches perpendicular to the first set of parallel trenches, spaces between the first and second sets of parallel trenches defining locations of thyristor memory cells; and forming an assist-gate electrode in each of the second set of parallel trenches, the assist-gate electrode adjacent to, but displaced from, a thyristor memory cell pair on opposite sides of the second set of parallel trenches to form an electrical coupling with the each of the thyristor memory cell pair.

Other objects, features, and advantages of the present invention will become apparent upon consideration of the following detailed description and the accompanying drawings, in which like reference designations represent like features throughout the figures.

### BRIEF DESCRIPTION OF THE DRAWINGS

FIG. 1 shows in a perspective view an exemplary array of thyristor memory cells according to one embodiment of the present invention.

FIG. 2 shows a semiconductor substrate at the beginning of the process flow to manufacture of the FIG. 1 thyristor memory cell array.

FIG. 3 shows a mask for an N-type implant to form buried N-well regions in the semiconductor substrate.

FIG. 4 shows a lightly doped P-type epitaxial layer over the substrate.

FIG. 5 shows a hard mask formed over the epitaxial layer of FIG. 4; the hard mask defines locations of trenches which will divide the thyristor memory cells in a first direction.

FIG. 6 shows the results of deep etching step to form a first set of trenches defined by the FIG. 5 mask.

FIG. 7 shows the results of an oxidation step which fills the trenches after a planarization step.

FIG. 8 shows after the results following an etch back of the oxide regions.

FIG. 9 shows the results of the stripping of the pad oxide and nitride layer followed by the deposition of another pad oxide and nitride layer.

FIG. 10 shows the results of the definition of a masking layer for the formation of a second set of trenches in the substrate perpendicular to the first set of trenches.

FIG. 11 shows the results of etching the second set of trenches.

FIG. 12 shows the results of the deposition of oxide on the sidewalls to the trenches.

FIG. 13 shows the results of the etching spacers.

FIG. 14 shows the results of the overetching the silicon in the trenches.

FIG. 15 shows the results of an N+ implant step into the bottom of the trenches.

FIG. 16 shows the results of depositing tungsten to fill the trenches which are then planarized. This is followed by etching back the tungsten in the trenches.

FIG. 17 shows the results of the filling the trenches with oxide, planarized and etched back the oxide in the trenches.

FIG. 18 shows the results of the oxidizing the trenches to form assist gate oxide layers on the trench sidewalls.

FIG. 19 shows the results of the deposition of tungsten into the trenches after the deposited tungsten is planarized. This tungsten is to form the assist-gate electrodes for the thyristor memory cells of the array.

FIG. 20 shows the results of the etchback of the tungsten in the trenches to form the assist-gate electrodes on the sidewalls of the trenches. FIG. 20A illustrates various arrangements of the assist-gates on the sidewalls of the trenches.

FIG. 21 shows the results of filling the trenches with oxide and planarizing the surface of the oxide.

FIG. 22 shows the results of masking and etching the formed pad oxide and nitride layers in the peripheral circuitry regions of the substrate while the thyristor memory cell array is masked.

FIG. 23 shows the results of etching trenches in peripheral circuitry regions as defined by the FIG. 22 mask.

FIG. 24 shows the results of depositing oxide into the FIG. 23 trenches which are then planarized.

FIG. 25 shows the results of recessed oxide after an etch back step.

FIG. 26 shows the results of stripping off the nitride layer and underlying pad oxide layer which forms the mask.

FIG. 27 shows the results after masking to define source/drain regions of the CMOS transistors in the peripheral circuitry region and implanting P-well and N channel CMOS transistors.

FIG. 28 shows the results after masking to cover the peripheral circuitry region and followed by a P-type implant for the P-base regions of the thyristor memory cells of the array.

FIG. 29 shows the results after masking to cover the peripheral circuitry region and followed by a N-type implant for the N-base regions of the thyristor memory cells of the array.

FIG. 29A illustrates the relative doping concentrations of the thyristor memory cells for optimum performance.

FIG. 30 shows the results after a gate oxide layer is deposited over the semiconductor device.

FIG. 31 shows the results of a polysilicon layer deposition, followed by a masking step and etching step to define polysilicon gate electrodes for CMOS transistors in the peripheral circuitry.

FIG. 32 shows the results after the polysilicon gate electrodes are oxidized to form sidewalls on the gate electrodes.

FIG. 33 shows the defined spacers on the sidewalls of polysilicon gate electrode after an etching step.

FIG. 34 shows the results of a masking step to define lightly P-type doped drain regions in the peripheral circuitry regions and the P-type implanting step.

FIG. 35 shows the results of a masking step to define lightly N-type doped drain regions in the peripheral circuitry regions and the N-type implanting step.

FIG. 36 shows the results of spacers formed on the sides of polysilicon gate electrodes after nitride layer deposition and etching steps.

FIG. 37 shows the mask for defining P-type source/drain regions for the CMOS transistors in the peripheral circuitry and a P-type implant step.

FIG. 38 shows the mask for defining N-type source/drain regions for the CMOS transistors in the peripheral circuitry and a N-type implant step.

FIG. 39 shows the results of depositing nickel-platinum over the semiconductor substrate, followed by an anneal step and an etching step to leave silicide regions for contact regions.

### DETAILED DESCRIPTION OF THE INVENTION

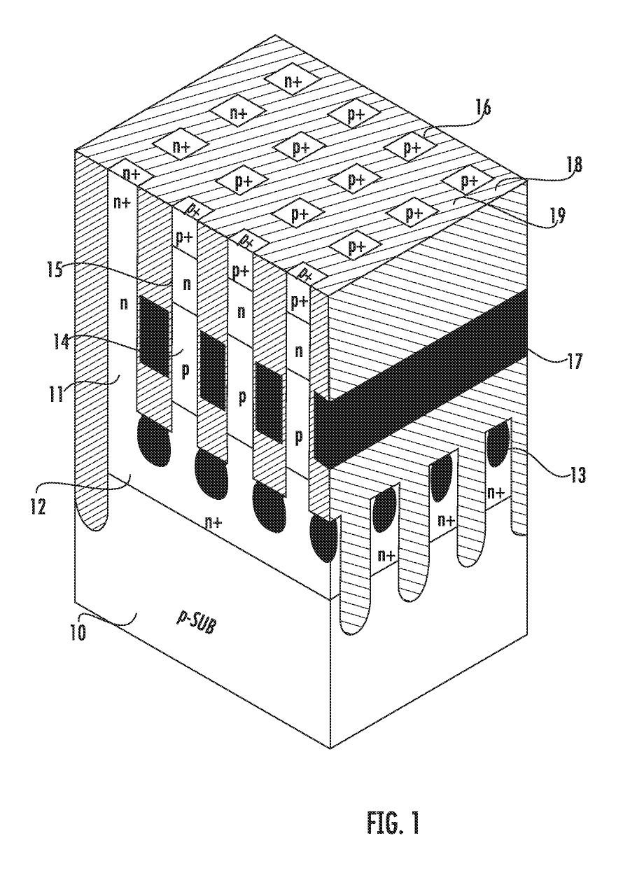

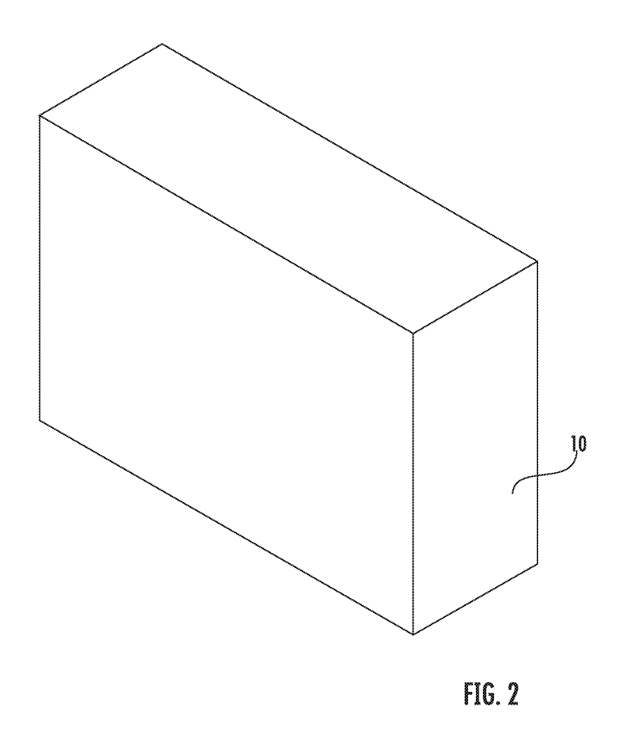

FIG. 1 is a perspective diagram illustrating a portion of a memory cell array according to one embodiment of present invention. The FIG. 1 array is not a complete integrated circuit device, but shows the array completed with the process steps of the embodiments of the invention.

The memory cell array is formed on a silicon substrate 10 in which nine complete (and four partial) vertical thyristors having P+ conductivity type anodes 16 are shown. (A commercial implementation of the array includes millions of such thyristors which form the memory cells.) The thyristors are separated from each other by dielectric isolation 18 between rows, and dielectric isolation 19 between columns, where rows and columns indicate perpendicular, but arbitrary, directions. Each thyristor includes a P+ conductivity type anode 16, an N− conductivity type base 15, a P− conductivity type base 14, and an N+ conductivity type cathode 12.

Metal, such as tungsten (W), assist-gate electrodes 17 extend in the row direction positioned in trenches between the thyristors and separated from the P− type base regions 14 by thin layers of an insulating material which may be the same as, or different from, the dielectric 18. Electrical operations which are performed to read data from and/or write data to an individual thyristor sometimes require application of a voltage to the assist-gate electrodes 17 on opposite sides of an individual thyristor. A heavily doped buried layer 12 serves as the cathodes of the thyristors and bit lines that extend through the structure in the column direction perpendicular to the assist-gate electrodes. Word lines are connected to the P+ anodes 16, not illustrated in this figure, and run in the row direction. Heavily doped regions 11 extend between the upper surface and the buried layer 12 to enable electrical connections to the buried N+ type well 12 which form the cathodes/bit lines. Metal, here tungsten, connections 13 short adjacent thyristors in the columns together to reduce minority carrier effects between adjacent cells. The connections 11 are typically positioned in the array in a periodic manner, i.e., a connection to the buried layer 12 is made every n array cells.

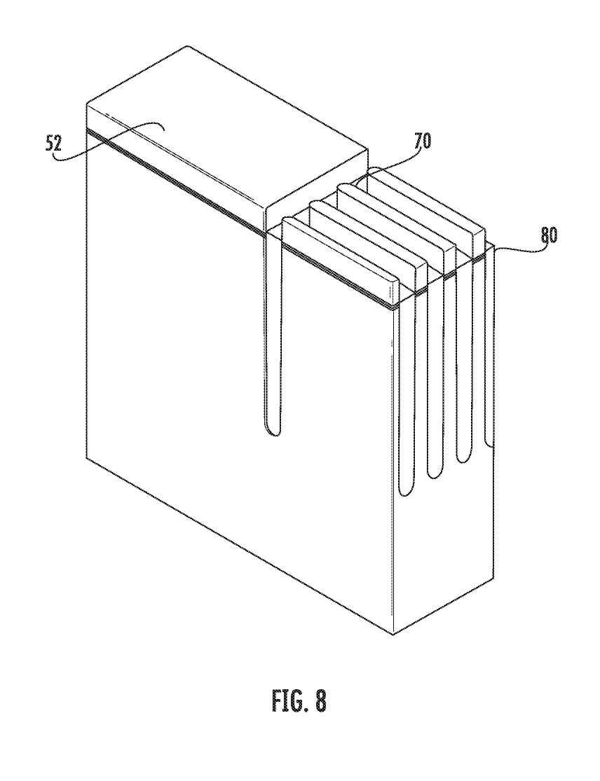

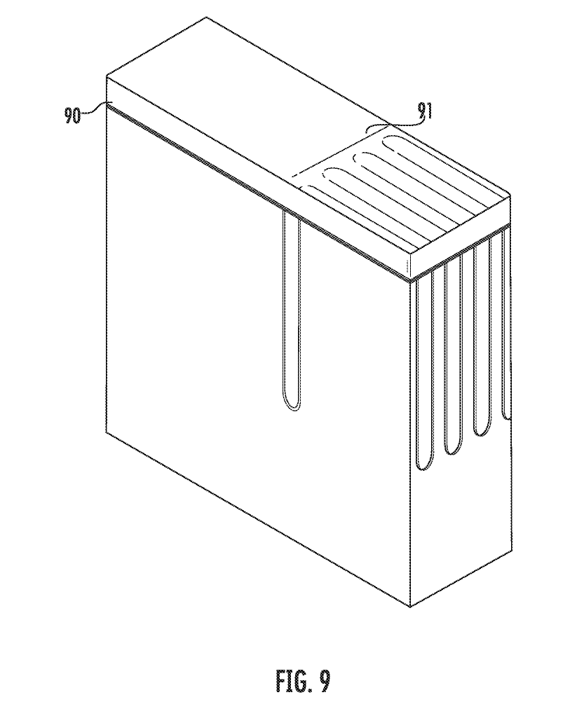

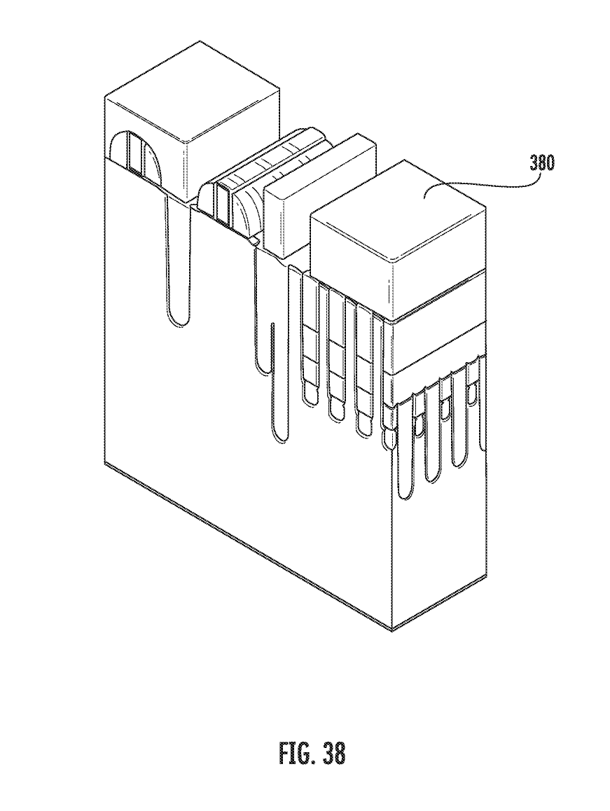

FIGS. 2-39 illustrate a preferred method for fabricating the thyristor DRAM cells shown in FIG. 1. In the description below some details and process steps are omitted as they are well-known to practitioners in the semiconductor field. Other methods are also discussed below. It should be noted that in the description below semiconductor device may refer to the array of thyristor memory cells at various stages of fabrication.

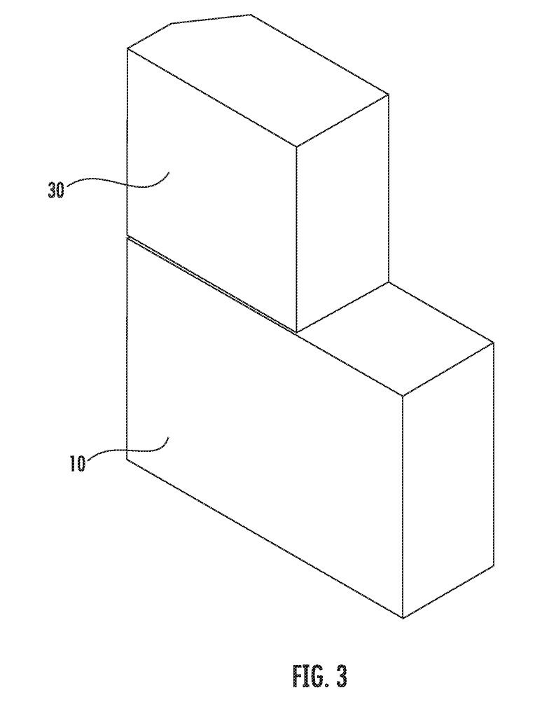

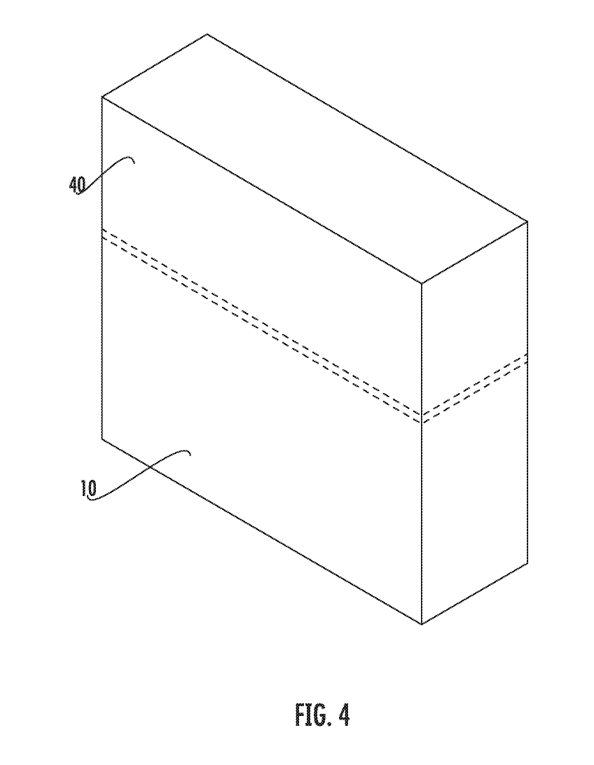

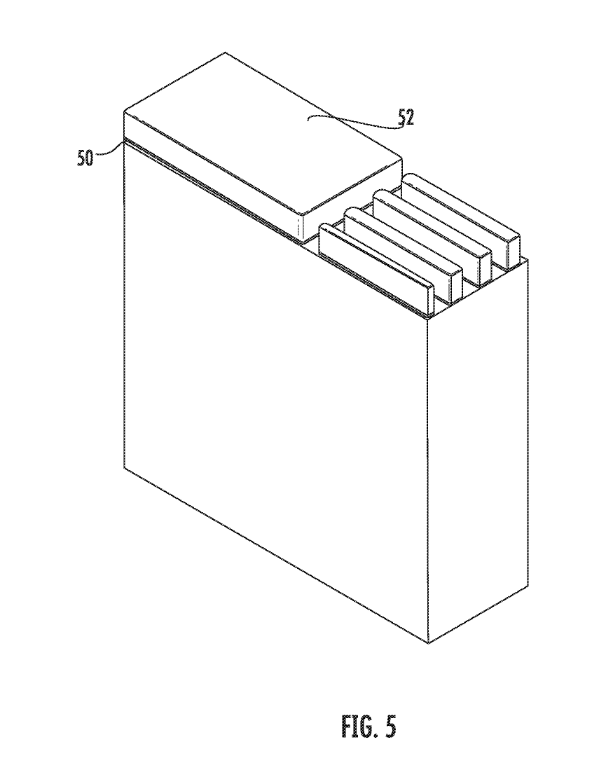

FIG. 2 illustrates a portion of a silicon substrate wafer 10 that provides a starting point for the process to be described next. The substrate 10 is a P− conductivity type. FIG. 3 illustrates a mask 30 applied to the surface of the wafer 10. The mask defines the location of the N conductivity type buried layer to be implanted into the wafer. As shown in FIG. 4, after implantation of the N+ buried layer which forms cathodes and a conducting cathode line (element 12 in FIG. 1) between thyristors, a layer of epitaxial silicon 40 is grown on the upper surface of wafer 10. Epitaxial layer 40 is lightly doped P conductivity type as it is grown, commonly known as in-situ doping.

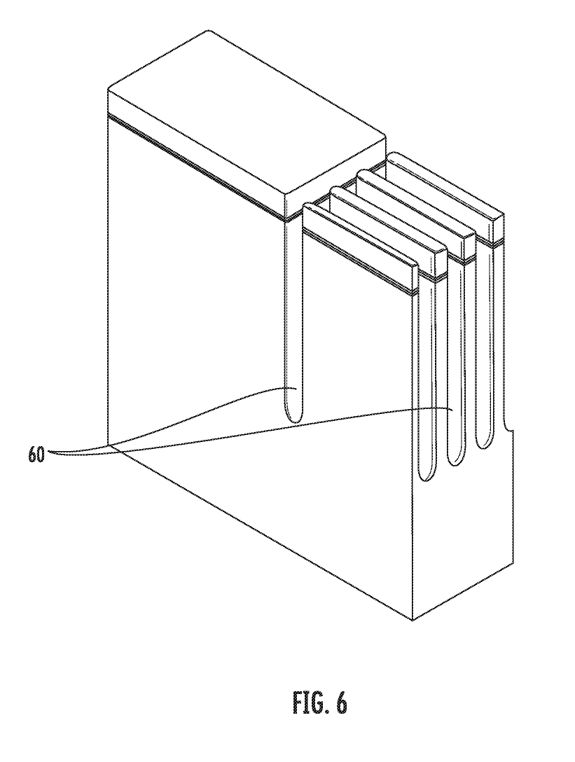

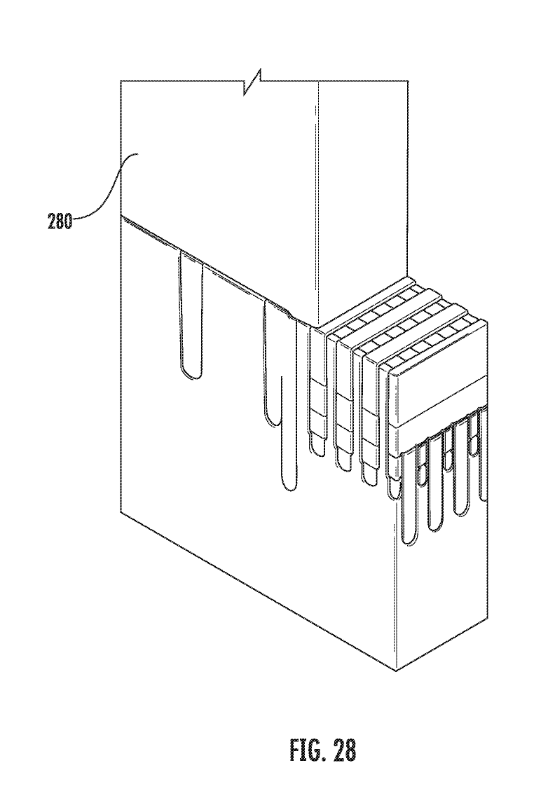

In an alternate process flow, deposition of the epitaxial silicon layer 40 is not performed until later in the process. In this alternate approach the process operations described in conjunction with FIGS. 5-27 are carried out on the semiconductor substrate rather than growing of the epitaxial layer. Before the base regions are implanted (see FIG. 28), the semiconductor device is etched away in the regions where the thyristor memory cells are to be formed, and epitaxial silicon is selectively grown inside these trenches to form the thyristor pillars. As the epitaxial silicon is grown it can be in-situ doped to provide the P and N type bases and the P type anodes.

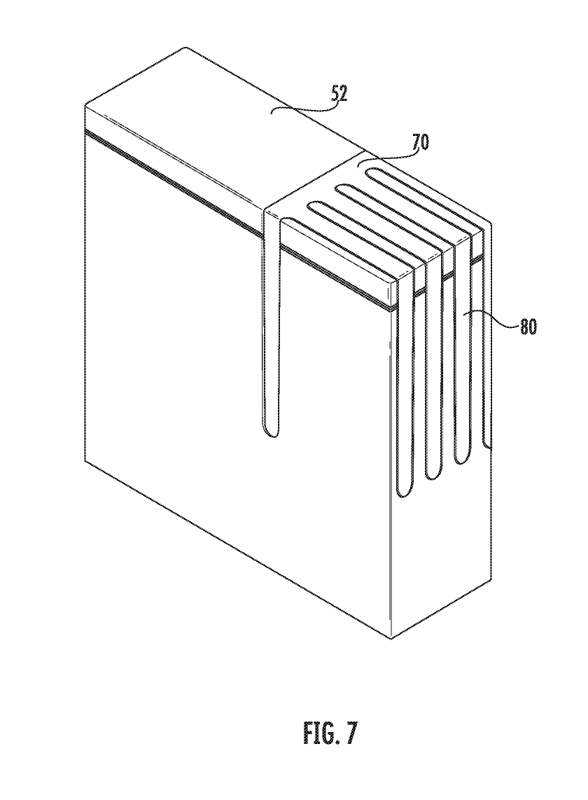

Returning to the preferred embodiment with epitaxial silicon deposited early in the process (as shown in FIG. 4), next, a thin layer of silicon dioxide 50, sometimes called a pad oxide, is formed on the upper surface of the epitaxial silicon, and a layer of silicon nitride 52 is formed on the oxide. The structure is then masked and etched, thereby defining a hard mask shown in FIG. 5 to be used in subsequent process steps. Using the hard mask, a deep etch of the wafer is performed to create trenches 60 extending down from the upper surface of the epitaxial layer 40 to the substrate 10. The trenches 60 are shown in FIG. 6 and extend linearly, in parallel in a first direction, shown in the drawing as the column or “Y” direction.

The structure is then oxidized and the trenches 60 filled with an insulating material, such as high-density plasma (HDP) chemical vapor deposition (CVD) silicon dioxide to create oxide regions 70 and 80. To return the upper surface of the semiconductor device to a plane, the surface is then chemically mechanically polished (CMP) with a stop upon reaching the nitride layer 52. The resulting structure is shown in FIG. 7. Then a reactive ion etch (ME) operation is performed to recess the oxide regions 70 and 80 below the upper surface of the nitride layer 52. The silicon dioxide (pad oxide) and silicon nitride layers 50 and 52 are then removed, and new layers of silicon dioxide 90 and silicon nitride 91 are formed. The appearance of the structure at this stage of the process is shown in FIG. 9.

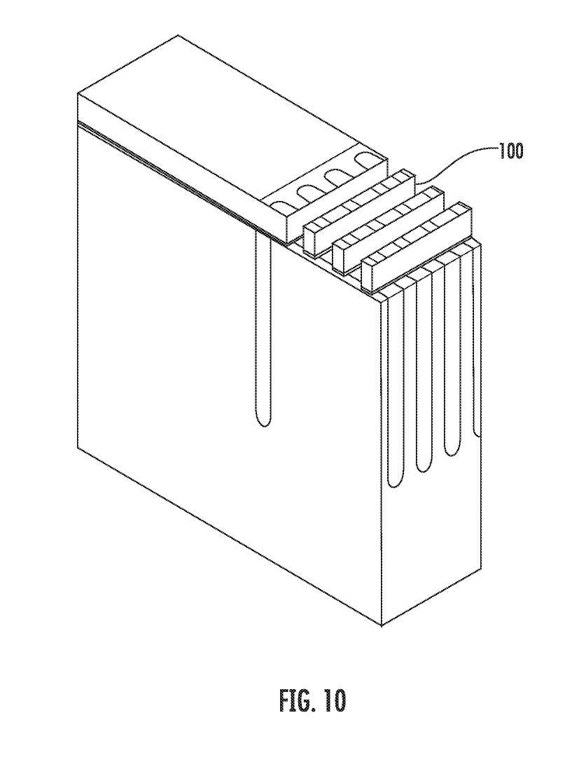

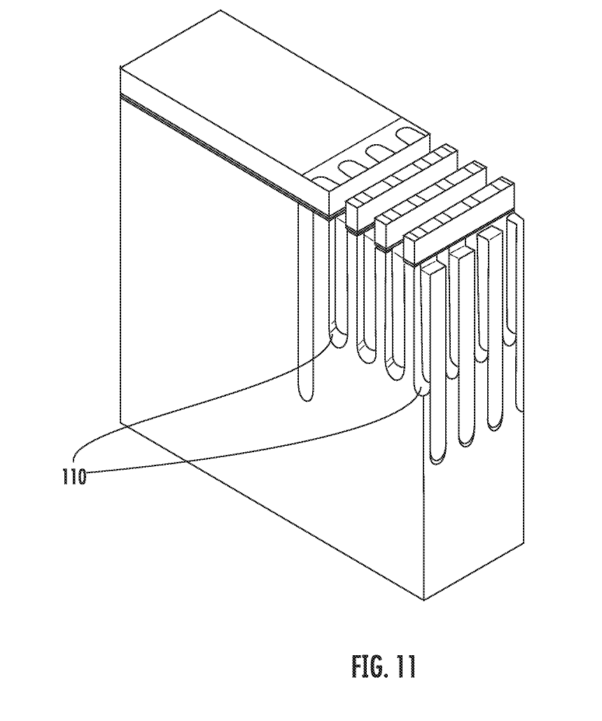

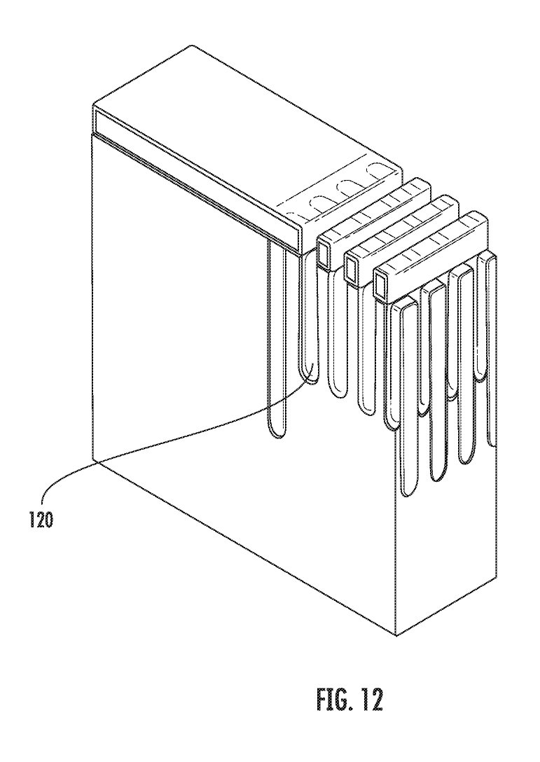

Further masking and etching steps are now performed to define a new hard mask 100 on the upper surface of the wafer, as shown in FIG. 10. Next as shown in FIG. 11, a second set of trenches 110 is etched as defined by the hard mask 100. The trenches 110 extend in a row or “X” direction, orthogonal to the previous set of trenches 60 which were in the column or “Y” direction. The intersections of the orthogonal trenches are used to create isolated “pillars” of silicon with which the thyristors are formed, as described below. (The sides and tops of the ultimate thyristor “pillars” are shown in FIG. 1.)

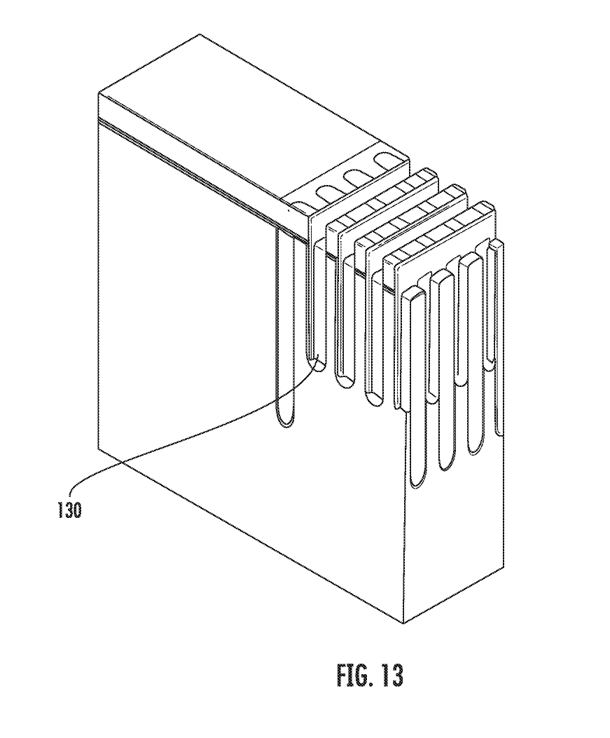

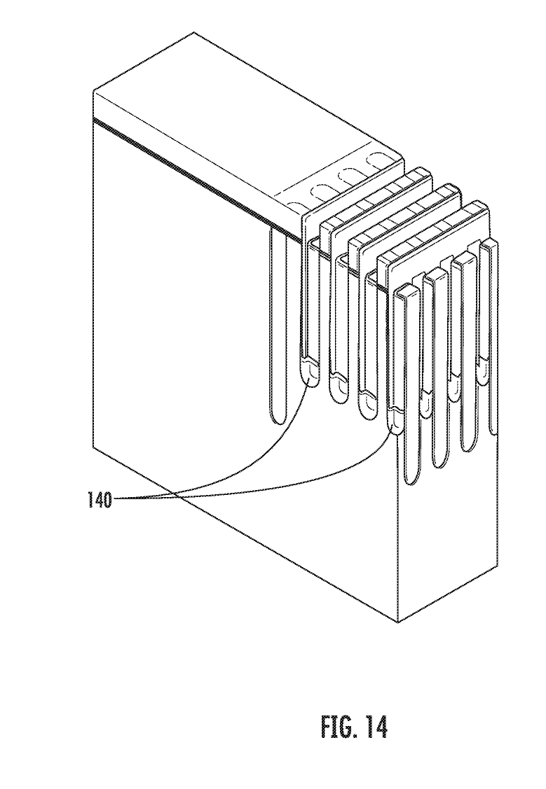

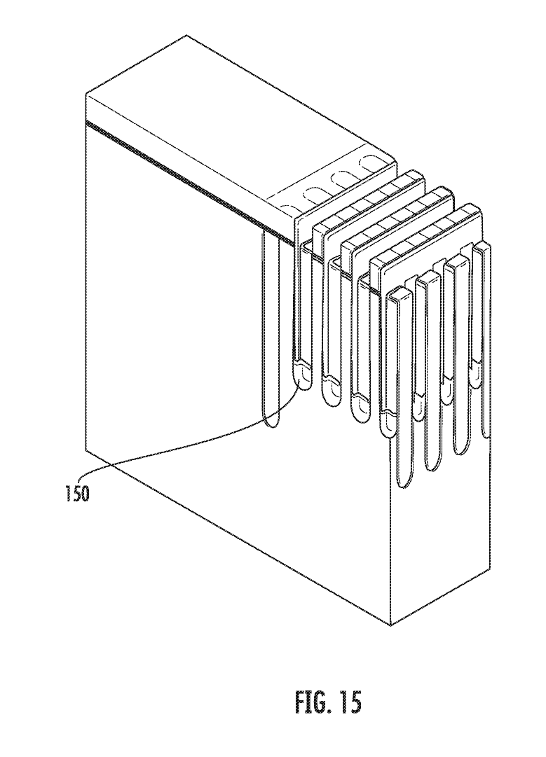

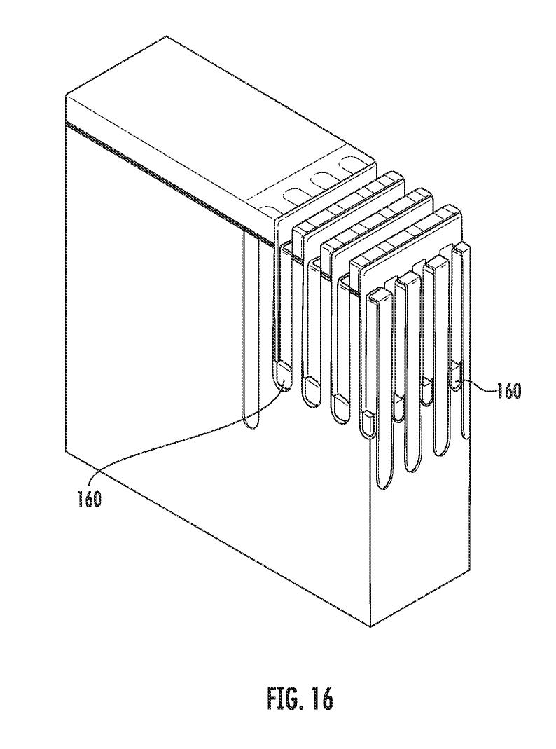

FIG. 12 illustrates the next step of the process in which sidewall oxide 120 is formed on the newly etched trench walls. As shown by FIG. 13, silicon dioxide spacers 130 are formed on the sidewalls by an anisotropic dry etch of the just deposited oxide and therefore clearing the oxide from the trench bottom. This step provides regions 140 at the bottoms of the trenches where conductive material will be deposited to connect adjoining thyristors, and is shown in FIG. 14. As shown by FIG. 15, an N conductivity type impurity is implanted into the trenches to create the lower doped regions 150 aligned by the over-etched silicon.

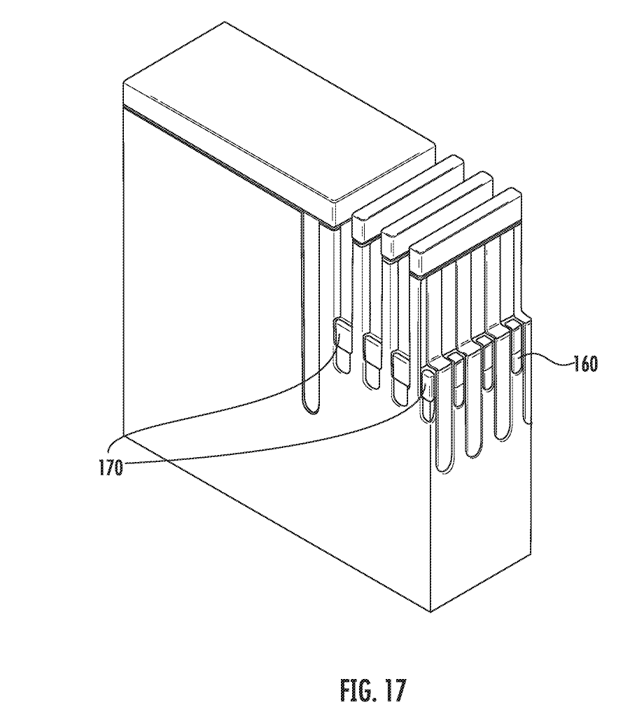

The trenches are then filled with a metal, here tungsten, layer and the CMP process performed to remove the tungsten deposited upon the upper surface of the structure. An etching step is then used to etch back the tungsten so that tungsten regions 160 remains only in the lower portions of the trenches as shown in FIG. 16. As is well known in the art, adhesion and barrier layers can be optionally deposited before the tungsten deposition.

With thyristor DRAM cells, holes (i.e., positive charges) are introduced into the buried layer (e.g., cathode/bit lines 12 of FIG. 1) when the thyristor switches states. This can cause a neighboring memory cell to change state, an undesirable circumstance. The tungsten regions 160 (or other conductive material) in the bottom of the trenches shorts adjoining thyristor cathodes together, lowering the lifetime of these minority holes significantly, and reducing the possibility of undesirable changes in state.

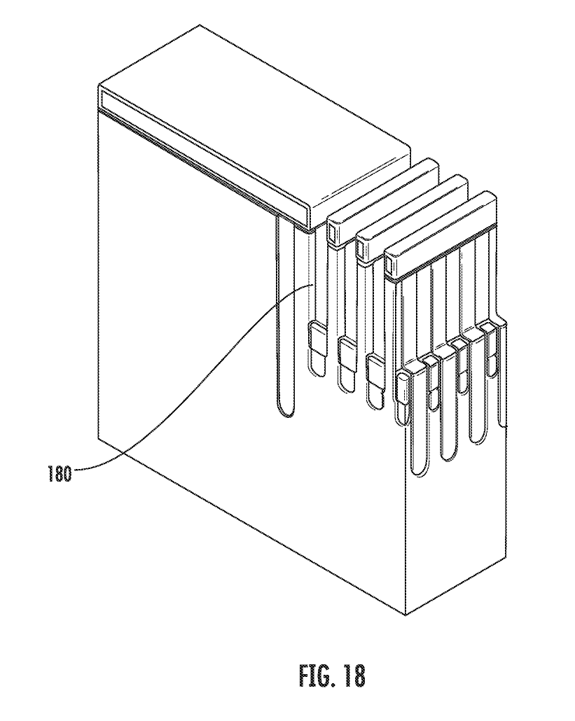

Next an oxide deposition step is used to fill the trenches 110 with an oxide layer 170, then the upper surface of the wafer is again flattened using a CMP process which stops on the nitride mask. Then a reactive ion etch step is used to etch back the oxide 170 to reduce its thickness upon the upper surface of the earlier deposited tungsten 160. This is shown in FIG. 17. The structure is then oxidized to form a gate oxide 180 on the sidewalls of the trenches 110 shown in FIG. 18.

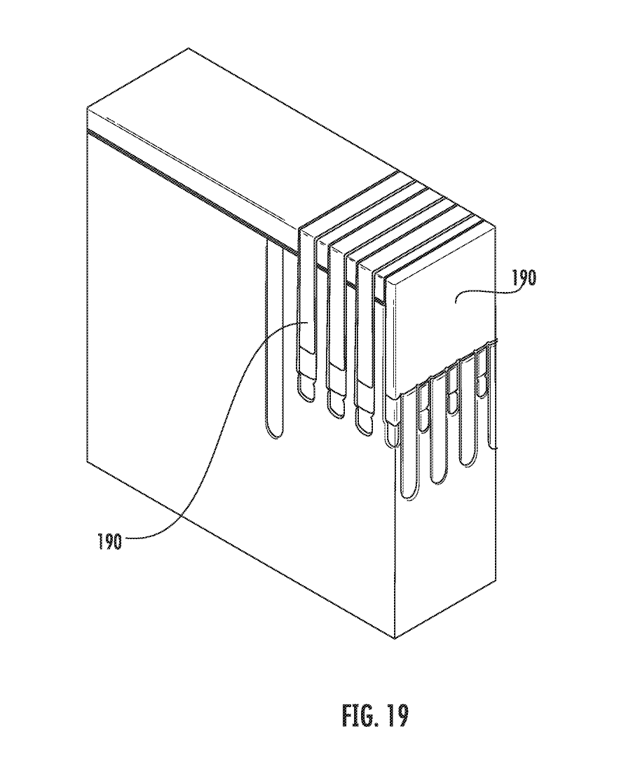

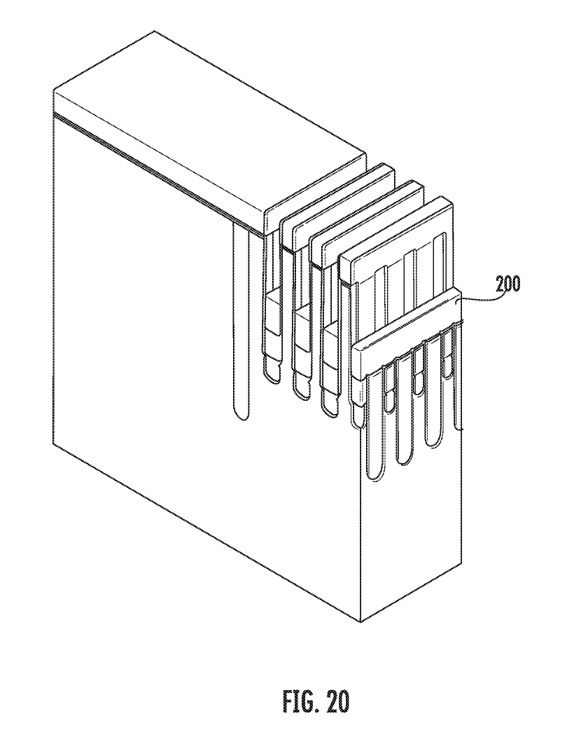

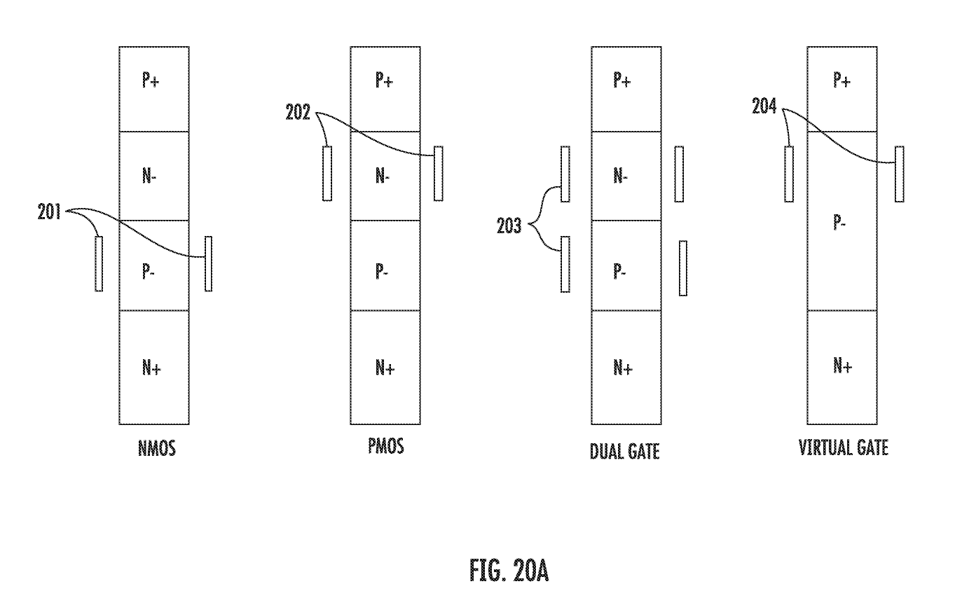

A tungsten layer 190 is again deposited to fill the trenches 110 and then planarized using a CMP process as shown in FIG. 19. The tungsten layer 190 provides the sidewall assist-gate electrodes for the thyristors formed in the array. In some embodiments an optional step is performed of depositing an optional work function metal, such as TiN, before the tungsten. The tungsten layer 190 is then etched back to the desired depth to form sidewall assist-gates electrodes 200 for the thyristors shown in FIG. 20.

Depending upon the ultimate structure desired, there are multiple possible locations for the sidewall assist-gate electrodes, which locations are shown in FIG. 20A. At the left-hand side of FIG. 20A, assist-gate electrodes 201 (one on each side of the P+ region) are illustrated for an NMOS structure. If a PMOS structure is desired, a pair of assist-gate electrodes 202 are formed higher up in the trenches 110 adjacent the N− regions, as shown in the second left-hand drawing of FIG. 20A. In some implementations a dual gate structure is desired, with two pairs of assist-gate electrodes 203 opposite both the N- and P-base regions. Formation of this structure requires repeating the steps described above to not only form the lower set of gate electrodes 201, but also the upper set of gates 202. Furthermore, in some implementations a virtual thyristor base is formed by omitting doping of the upper lightly doped N-base region, instead using a pair of assist-gate electrodes 204 to invert the P− conductivity type with application of suitable potentials, as illustrated in the right-most drawing of FIG. 20A. In this implementation the potential applied to the gate electrodes 204 inverts the lightly doped P region to create a virtual N region.

In each of the implementations shown in FIG. 20A, the trench adjoining the thyristor structure has only a single assist-gate per trench. Each assist-gate electrode is adjacent to, but displaced from, the base regions of pairs of thyristor memory cells on each side of the assist-gate electrode 200 to electrically couple with the each of the thyristor memory cell pair. This contrasts with prior art approaches of using two assist-gates per trench, that is, a separate assist-gate for each of the two thyristors on opposite sides of the trench. The use of a single assist-gate per trench reduces the surface area required for the array, thus reducing cost per memory cell and increasing density of the array. Use of a single assist-gate per trench, however, requires additional decoding circuitry to access a single memory cell, because the assist-gate electrode in the trench on each side of the thyristor is activated to access the thyristor for selected read, write or refresh operations.

As described above, in the preferred embodiment the assist-gate electrodes in FIG. 20A are formed with tungsten. In alternate embodiments other conductive materials can be used to adjust the bias voltage(s) needed for cell operations. For example, polysilicon, TiN, cobalt, and titanium, may be used.

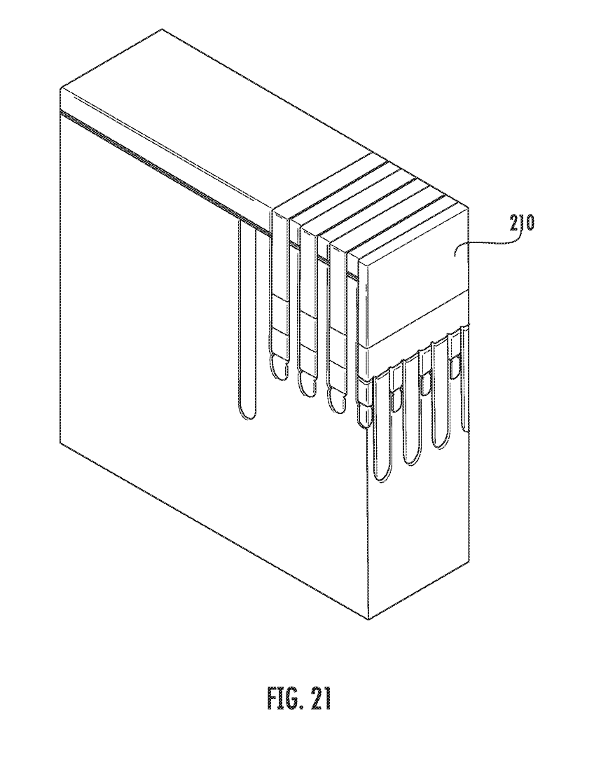

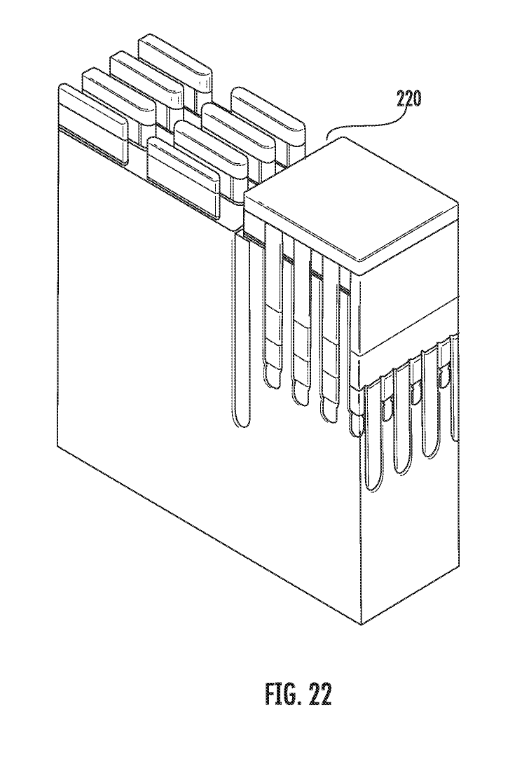

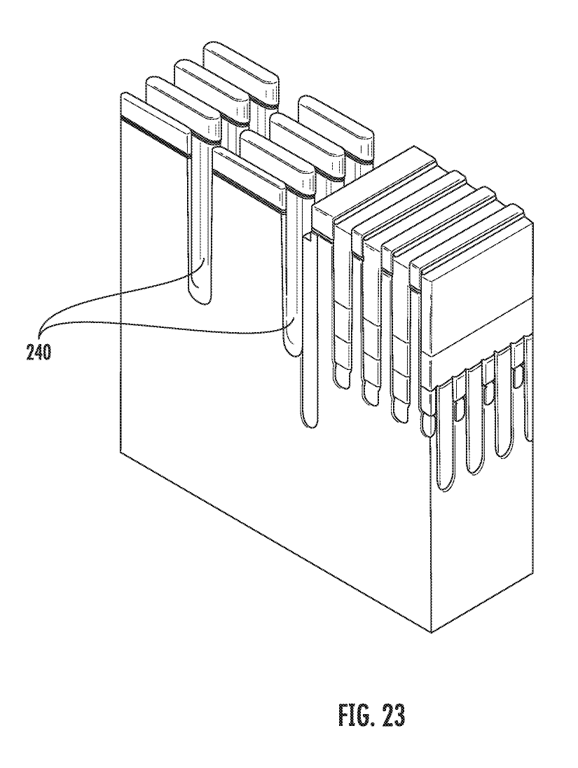

The description of the remaining process assumes that an NMOS structure is desired, i.e. as per gates 201 on the left side of FIG. 20A. In the next step a high density plasma (HDP) oxide layer 210 is deposited to fill the trenches 110. The upper surface of the oxide layer 210 is again planarized with a CMP operation with the nitride layer acting as a stop. The results are shown in FIG. 21. Next, as shown in FIG. 22 a mask is used to define regions protect the thyristor array and expose regions where peripheral circuitry for the memory cell array is to be formed. The peripheral circuitry provides appropriate read, write, and access signals for the thyristor memory cell of the array. With the mask definition the nitride and pad oxide layers are then etched to expose upper portions 220 of the surface of the wafer. FIG. 23 illustrates the etching of trenches 240 where the peripheral circuitry is formed. These trenches isolate active regions of the peripheral circuitry semiconductor structure from other active regions.

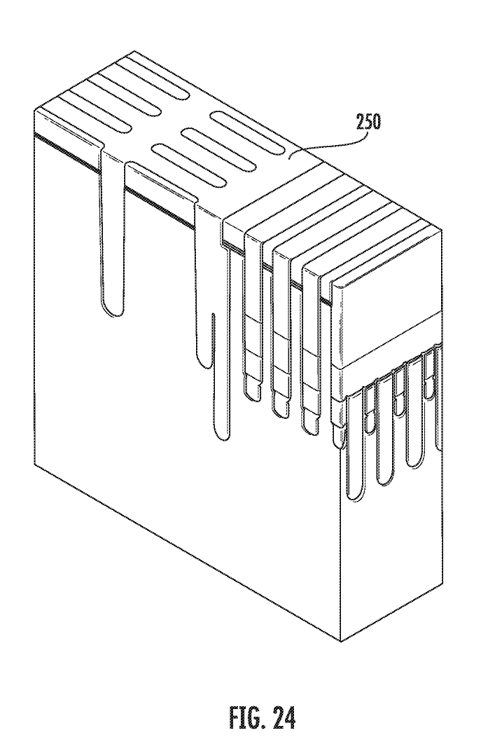

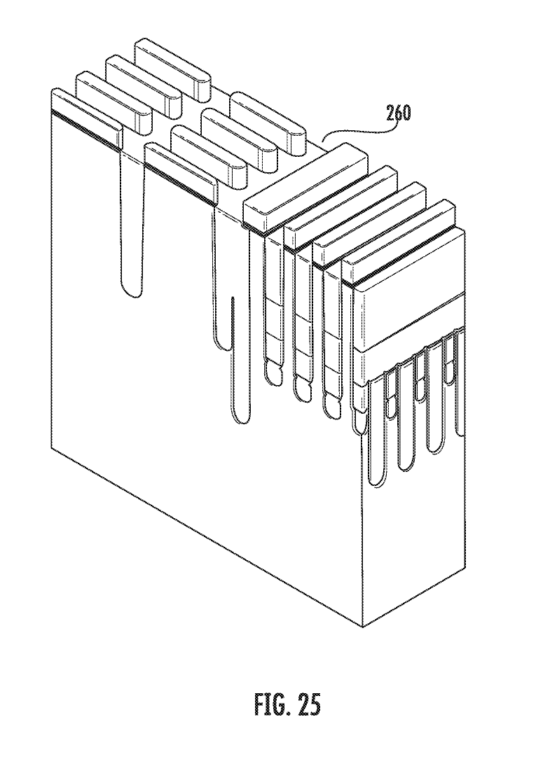

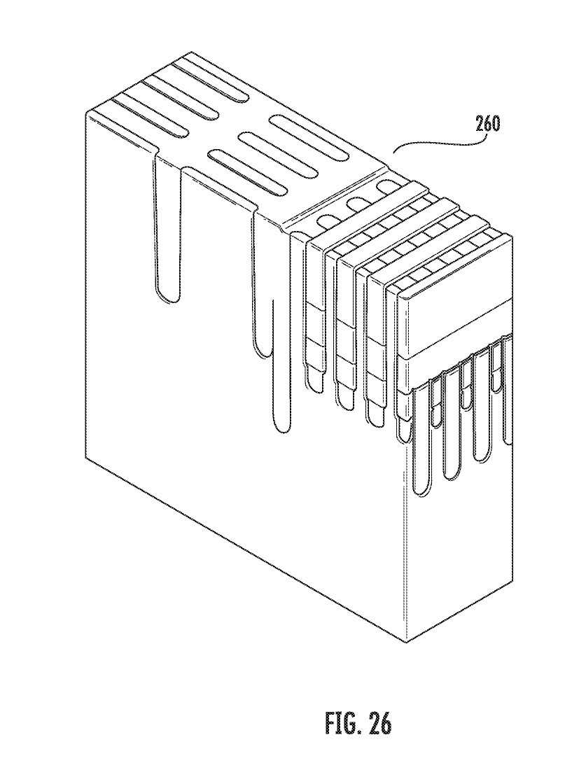

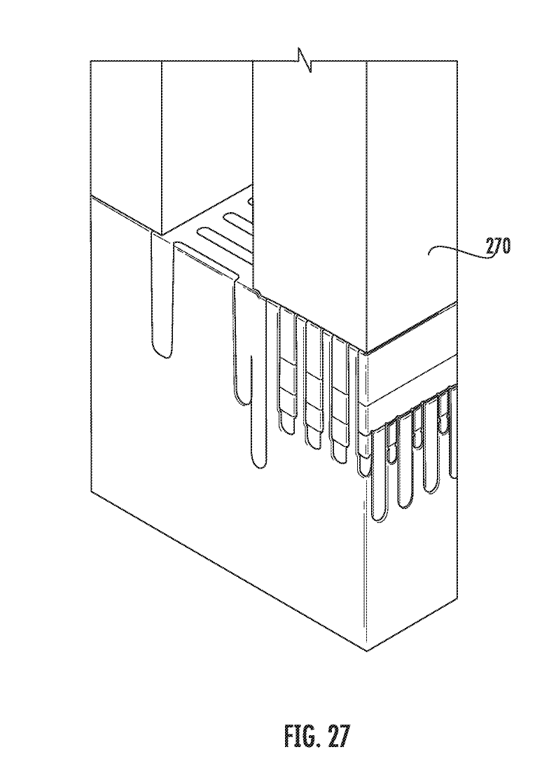

As shown in FIG. 24, HDP oxide 250 is then deposited to fill the trenches, and a further CMP step performed which stops on the nitride layer. A reactive ion etching (RIE) step is then performed to recess the oxide. The recessed oxide 260 is illustrated in FIG. 25. The nitride and underlying pad oxide layers are removed from the wafer surface, as shown in FIG. 26. In FIG. 27 a new mask 270 is applied to define locations where the P-well and N-channel CMOS devices are to be formed. After masking, these regions are implanted.

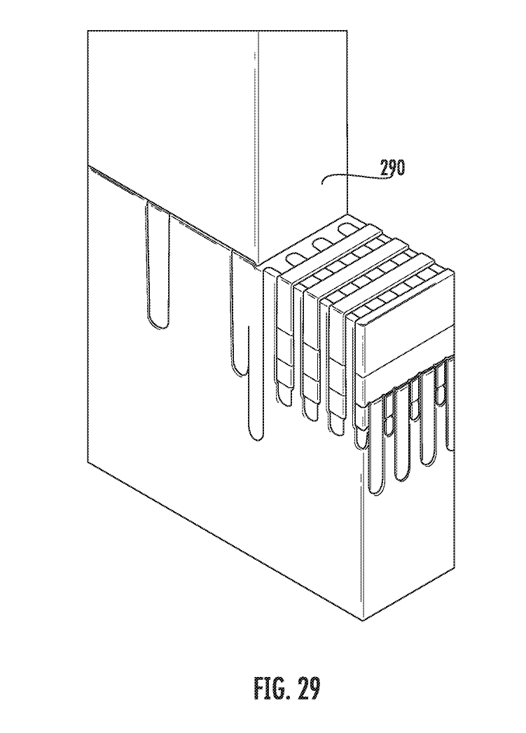

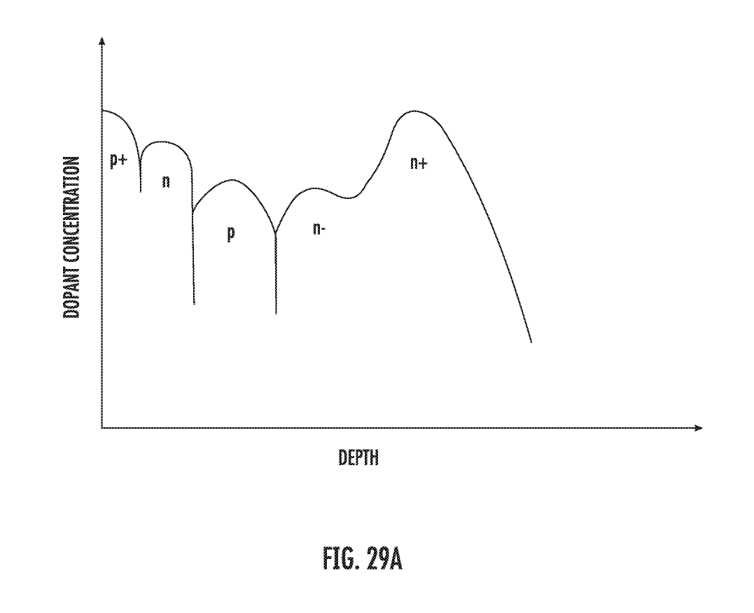

Next, as shown in FIG. 28, another mask 280 is formed to cover the peripheral circuitry and the P type base regions of the thyristors are implanted. FIG. 29 illustrates a further mask 290 over the peripheral regions of the semiconductor structure to enable implanting of the N type base regions of the thyristors, and to enable implanting the buried N+ cathode pickup regions. The implanted N+ pickup regions provide electrical connection to the buried cathode/bit lines.

FIG. 29A illustrates a preferred doping profile for the thyristors. This doping profile has the advantage of making the thyristors less sensitive to temperature changes. In particular, the vertical PNPN thyristor doping is designed to make the temperature coefficients of the gains of the constituent PNP and NPN bipolar transistors which theoretically form a PNPN thyristor, of opposite polarity. Heavily doping the P+ anode and lightly doping the N base gives the PNP common emitter gain a positive temperature coefficient. Doping the N+ cathode the same or slightly lower than the P-base gives the NPN common emitter gain a negative temperature coefficient. The doping profile and resulting gains of opposing polarity make the net thyristor loop gain less temperature dependent.

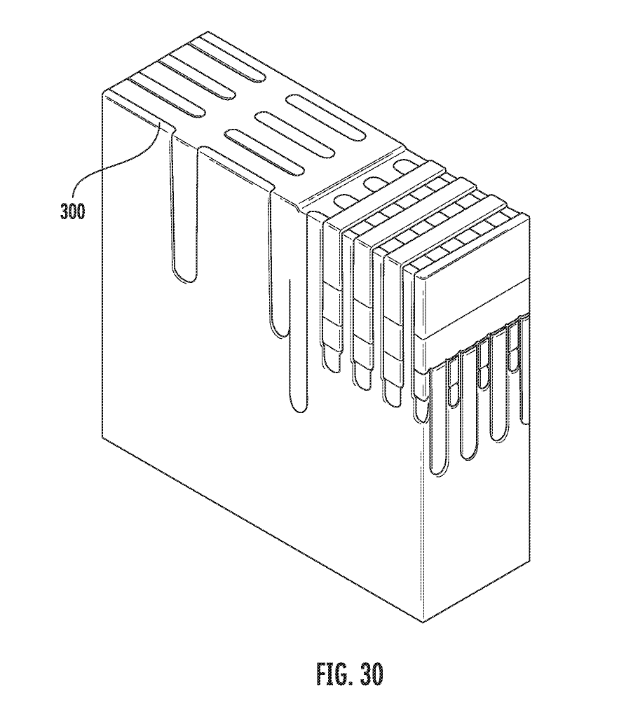

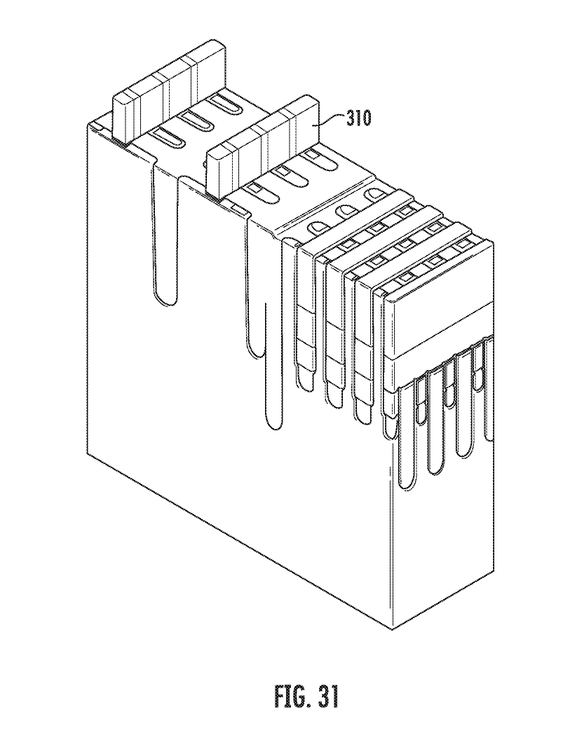

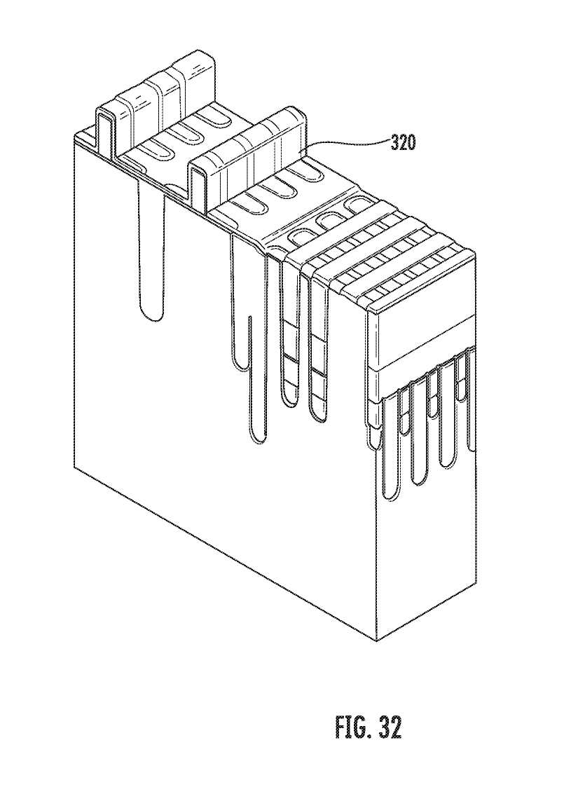

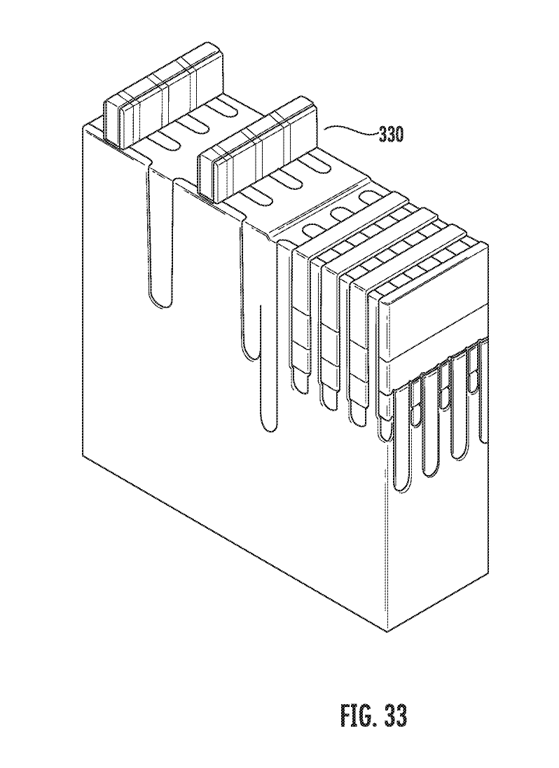

Returning to the manufacturing process flow, a new gate oxide layer 300 is formed over the peripheral circuitry areas of the wafer as shown in FIG. 30. A polysilicon layer 310 is then deposited over the oxide layer 300. The polysilicon layer is then masked and etched to form gates 310 for the CMOS devices in the peripheral region as illustrated by FIG. 31. An oxidation process step follows so that the polysilicon gates 320 are formed with oxide sidewalls, as shown in FIG. 32. A reactive ion etch is then performed to define gate sidewall spacers 330 shown in FIG. 33 for subsequent implantation steps during which lightly doped drain (LDD) CMOS transistor pairs will be formed.

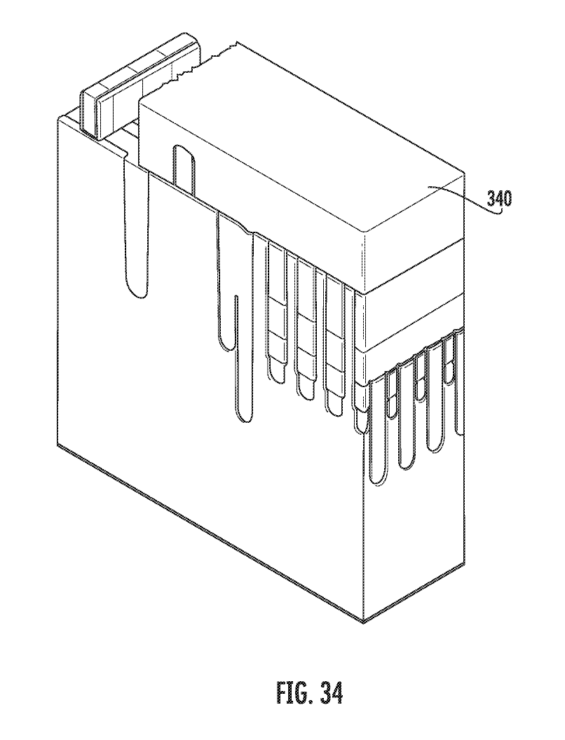

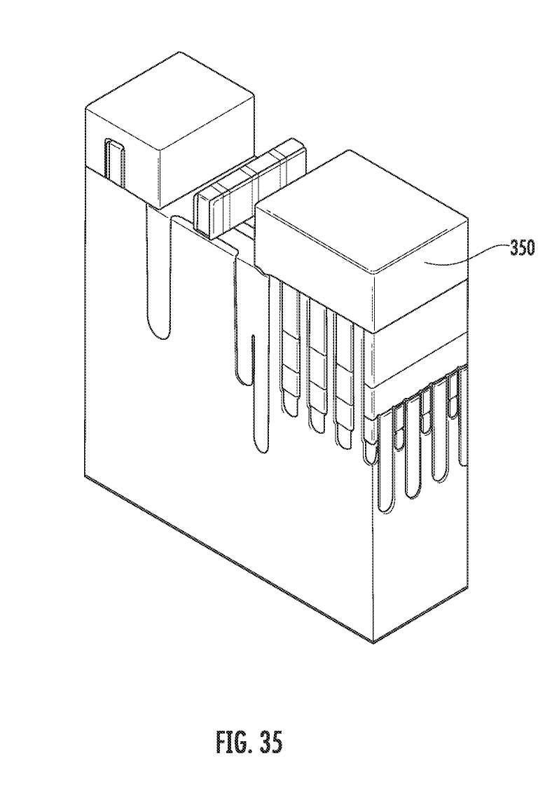

To form the LDD regions, a new mask 340 is formed across the surface of the wafer as shown in FIG. 34 to enable implantation of lightly doped P type drain regions for the CMOS devices in the peripheral circuitry. After P type implantation, another mask 350 shown in FIG. 35 is formed on the upper surface of the wafer to enable implantation of the lightly doped N type regions for the CMOS devices in the peripheral circuitry. The lightly doped N type drains are then implanted.

The next steps of the process flow are directed toward the creation of the source/drain regions of CMOS transistors in the peripheral circuitry. A silicon nitride is deposited on the wafer and etched to define spacer regions 360 for the gates of the CMOS transistors as shown in

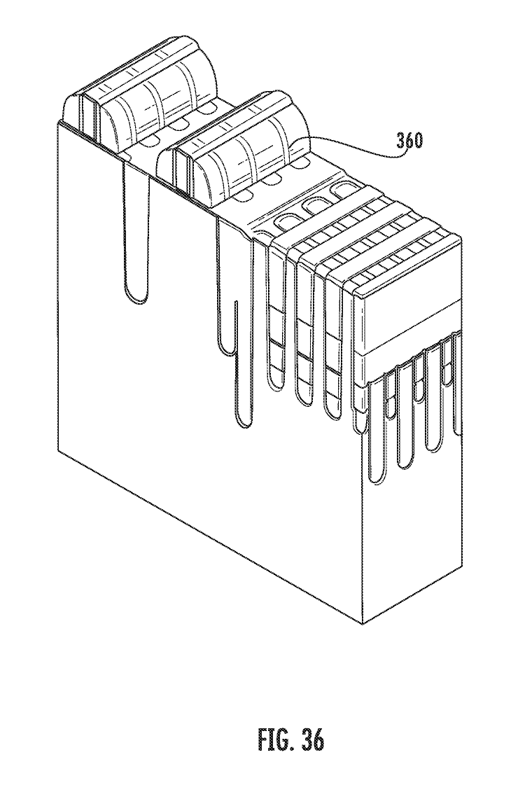

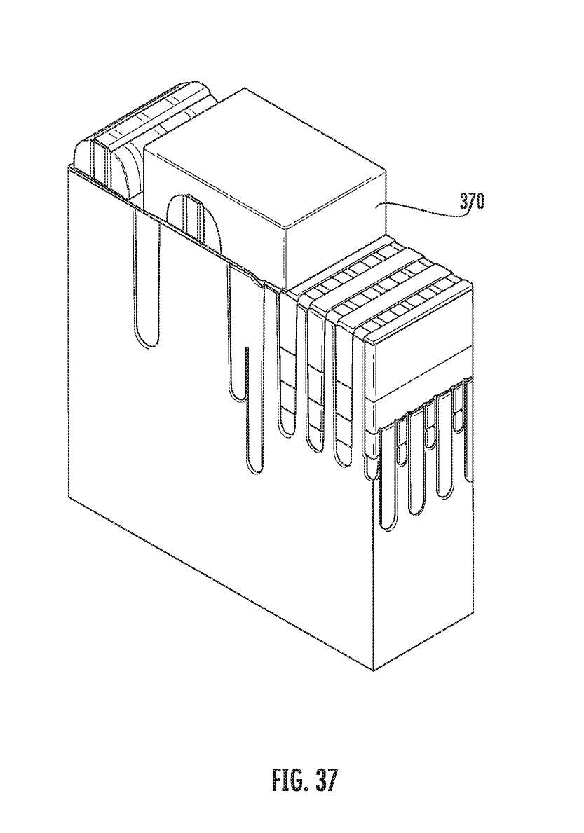

FIG. 36. Another mask 370 shown in FIG. 37 is formed to enable implantation of P type source and drain regions of the CMOS transistors, as well as the P+ thyristor anodes. After the mask 370 is removed, another mask 380 is created which defines the N type source and drain regions of the CMOS transistors and an N-type implantation step follows accordingly.

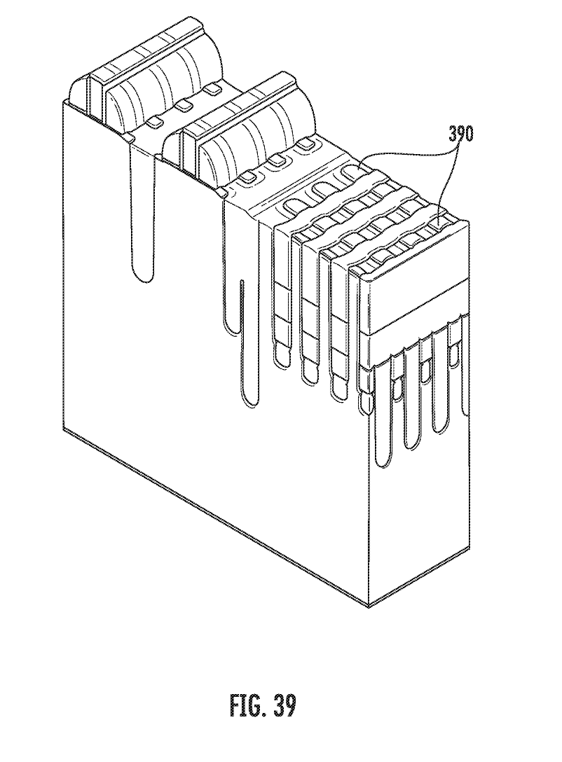

Finally, a nickel-platinum layer is deposited across the upper surface of the wafer, and an annealing operation is performed to make silicide electrical connections 390 to the thyristor P+ regions in the array, and the unreacted portions of the nickel-platinum layer are removed by etching. The results are shown in FIG. 39. During this step silicide electrical connections are also made to the N+ buried layer providing electrical connections to that region and silicide electrical connections are made to desired parts of the peripheral circuitry on the wafer. Further process steps which are not described include the creation of conducting lines connected to the P+ thyristor anodes and to the N+ buried layers forming the cathodes/bit lines of the memory cells, and to the various source and drain regions of the CMOS transistors of the periphery circuitry.

This description of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications. This description will enable others skilled in the art to best utilize and practice the invention in various embodiments and with various modifications as are suited to a particular use. The scope of the invention is defined by the following claims.

The invention claimed is:

1. An integrated circuit array of thyristor memory cells comprising:
a set of cathode lines;
a set of anode lines;
a plurality of thyristor memory cells arranged in an array, each thyristor memory cell having a cathode region connected to a cathode line and an anode region connected to an anode line and at least one base region between the cathode region and anode region; and
a set of assist-gate electrodes, each assist-gate electrode located between pairs of thyristor memory cells, a portion of the assist-gate electrode adjacent to, but displaced from, the at least one base region of each of the thyristor memory cell pair to form an electrical coupling with the each of the thyristor memory cell pair.

2. The integrated circuit array of claim 1 further comprising a semiconductor substrate wherein the plurality of thyristor memory cells are arranged over the substrate and each of the thyristor memory cells comprises a layered structure of alternating electrical conductivities, the layered structure arranged perpendicular to the substrate.

3. The integrated circuit array of claim 2 wherein the set of assist-gate electrodes are between the set of cathode lies and the set of anode lines located

4. The integrated circuit array of claim 1 wherein the set of assist-gate electrodes comprises a conductive material selected to control a bias voltage for a thyristor memory cell, the bias voltage applied to the assist-gate electrode for switching the state of the thyristor memory cell.

5. The integrated circuit array of claim 2 wherein the conductive material is tungsten, polysilicon, titanium, titanium nitride, or cobalt.

6. The integrated circuit array of claim 1 wherein the at least one base region comprises a first conductivity type region, and each thyristor memory cell further comprises a second base region, the second base region comprises a second conductivity type, and a portion of a second assist-gate electrode adjacent to, but displaced from, the second base region.

7. The integrated circuit array of claim 6 wherein the first assist-gate electrode and second assist-gate electrode are parallel to each other.

8. The integrated circuit array of claim 1 wherein the at least one base region comprises a sufficient low conductivity region such that application of the assist-gate electrode inverts the region to an opposite conductivity.

9. The integrated circuit array of claim 8 wherein the at least one base region comprises a P-type conductivity region.

10. The integrated circuit array of claim 9 wherein each thyristor memory cell comprises only one base region.

11. The integrated circuit array of claim 1 wherein the at least one base region comprises a first conductivity type region, and each thyristor memory cell further comprises a second base region, the second base region comprises a second conductivity type, wherein the cathode region, anode region, the at least one base region and the second base region having doping profiles to reduce temperature sensitivity of the thyristor memory cell.

12. The integrated circuit array of claim 11 wherein the anode region, second base region and the at least one base region define a PNP bipolar transistor, and the second base region, the at least one base region and the cathode region define an NPN bipolar transistor, gains of the PNP and NPN transistors having opposing temperature coefficients to reduce temperature sensitivity of the thyristor memory cell.

13. The integrated circuit array of claim 12 wherein the anode region is heavily positively doped and the second base region is lightly positively doped for a PNP common emitter gain with a positive temperature coefficient for the defined PNP bipolar transistor, and the cathode region is negatively doped the same or slightly less than the at least one base region is positively doped for a common emitter gain with a negative temperature coefficient for the defined NPN bipolar transistor.

14. A method of fabricating an integrated circuit array of thyristor memory cells comprising:
forming a first set of parallel trenches in a semiconductor substrate;
forming a second set of parallel trenches in the semiconductor substrate, the second set of parallel trenches perpendicular to the first set of parallel trenches, spaces between the first and second sets of parallel trenches defining locations of thyristor memory cells; and
forming an assist-gate electrode in each of the second set of parallel trenches, the assist-gate electrode adjacent to, but displaced from, a thyristor memory cell pair on opposite sides of the second set of parallel trenches to form an electrical coupling with the each of the thyristor memory cell pair.

15. The method of claim 14 further comprising:
forming all conductive layers at the defined locations to form the thyristor memory cells by epitaxial deposition.

16. The method of claim 15 wherein the step of forming all conductive layers at the defined locations is performed after the step of forming an assist-gate electrode.

17. The method of claim 15 wherein the step of forming all conductive layers further comprises
alternating dopant polarities during epitaxial deposition to form alternating conductive layers for the thyristor memory cells.

18. The method of claim 14 further comprising:
forming some layers of conductive layers at the defined locations to form the thyristor memory cells by ion implantation.

19. The method of claim 18 wherein the step of forming some layers of conductive layers at the defined locations comprises ion implantation of dopants of alternating polarities to create conductive layers of alternating polarities at the top of the thyristor memory cells.
